(19) United States
(12) Patent Application Publication
(10) Pub. No.: US 2025/0151489 A1
(43) Pub. Date: May 8, 2025

(54) Display Device

(71) Applicant: LG Display Co., Ltd., Seoul (KR)

(72) Inventors: Dae Han Won, Paju-si (KR); Kyoung June Jung, Paju-si (KR); Chan Woo Im, Paju-si (KR); Jeen Wook Kwon, Paju-si (KR)

(21) Appl. No.: 18/925,989

(22) Filed: Oct. 24, 2024

(30) Foreign Application Priority Data
Nov. 7, 2023 (KR) 10-2023-0152708

(51) Int. Cl. H01L 33/62; H01L 25/16

(52) U.S. Cl. CPC H10H 20/857; H01L 25/167

(57) ABSTRACT

A display device includes a substrate including a display area and a non-display area, a plurality of pixels in the display area, wherein each pixel of the plurality of pixels includes a plurality of sub-pixels, at least one driving circuit unit configured to drive the plurality of pixels, a first protrusion and a second protrusion that are disposed in at least one pixel of the plurality of pixels, a first electrode formed on the first protrusion and the second protrusion, a light emitting unit disposed on the first electrode, and a second electrode disposed on the light emitting unit and connected to the light emitting unit, wherein the first protrusion and the second protrusion may have different widths in a second direction.

### CROSS-REFERENCE TO RELATED APPLICATION

This application claims priority to and the benefit of Republic of Korea Patent Application No. 10-2023-0152708, filed on Nov. 7, 2023, which is hereby incorporated by reference in its entirety.

### BACKGROUND

### 1. Field of Technology

The present disclosure relates to a display device. More specifically, the present disclosure relates to a device in which the connection between a second electrode and a connecting electrode can be improved in a display device using a micro light emitting diode.

### 2. Discussion of Related Art

Liquid crystal display devices and organic light emitting display devices are being utilized as flat panel type display devices.

Compared to the liquid crystal display device, the organic light emitting display device has advantages of increased luminous efficiency, a fast response time, a wide viewing angle, etc. However, since the organic light emitting display device still has low luminous efficiency and is vulnerable to moisture due to containing organic materials, reliability and lifetime may be reduced.

Recently, micro light emitting diode display devices, which are inorganic light emitting display devices, have been proposed.

A micro light emitting diode display device implements images by arranging an inorganic light emitting diode having a size of 100 μm or less in each pixel. In the micro light emitting diode display device, micro light emitting diodes grown on a single crystal substrate may be disposed on an array substrate of the display device and connected to electrodes.

### SUMMARY

An array substrate is provided by forming pixel driving circuits and wiring layers on a substrate of a display device.

A first electrode connected to a micro light emitting diode element (hereinafter referred to as a “light emitting element”) may be disposed on the array substrate of the display device, and after the light emitting element is disposed on the array substrate, a second electrode connected to the light emitting element may be disposed on the array substrate.

The first electrode may apply a high potential voltage or a low potential voltage to the light emitting element, and the second electrode may apply a low potential voltage or a high potential voltage to the light emitting element to drive the light emitting element. The first electrode may be connected to a first surface of the light emitting element, and the second electrode may be connected to a second surface of the light emitting element.

The second surface of the light emitting element may be an upper surface of the light emitting element, and the first surface of the light emitting element may be a lower surface of the light emitting element. To bring a pixel driving circuit disposed on the substrate into contact with the second electrode connected to the second surface of the light emitting element, the second electrode may be disposed in a contact hole deeper than a height of the light emitting element. As the depth of the contact hole increases, an angle of the contact hole may be formed differently from the design, causing cracks in the second electrode.

Therefore, the inventors of the present disclosure have invented a display device in which reliability can be improved by improving the connection between the second electrode connected to the upper surface of the light emitting element and a driving circuit unit disposed under the light emitting element.

The objects according to embodiments of the present disclosure are not limited to the above-described objects, and other objects that are not mentioned will be clearly understood by those skilled in the art from the following description.

A display device according to embodiments of the present disclosure includes a substrate including a display area and a non-display area, a plurality of pixels in the display area, wherein each pixel of the plurality of pixels includes a plurality of sub-pixels, at least one driving circuit unit configured to drive the plurality of pixels, a first protrusion and a second protrusion that are disposed on at least one of the plurality of pixels, a first electrode formed on the first protrusion and the second protrusion, a light emitting unit disposed on the first electrode, and a second electrode disposed on the light emitting unit and connected to the light emitting unit, wherein the first protrusion and the second protrusion may have different widths in a second direction.

A display device according to embodiments of the present disclosure includes a substrate including a display area and a non-display area disposed on at least one side of the display area, a driving circuit unit disposed in the display area, and a plurality of pixels electrically connected to the driving circuit unit, wherein each of the plurality of pixels includes a plurality of sub-pixels, at least two light emitting elements are disposed in each of the plurality of sub-pixels, the light emitting elements are electrically connected to the driving circuit unit via a first connecting electrode and a second connecting electrode, and the first connecting electrode is formed on first and second protrusions and the second connecting electrode is formed on the second protrusion.

Specific details of other embodiments are included in the detailed description and the accompanying drawings.

### BRIEF DESCRIPTION OF THE DRAWINGS

FIG. 1 is a plan view showing a display device according to one embodiment of the present disclosure.

FIG. 2 is an enlarged plan view of a pixel portion of FIG. 1 according to one embodiment of the present disclosure.

FIG. 3 is a cross-sectional view taken along line A-A′ of FIG. 2 according to one embodiment of the present disclosure.

FIG. 4 is an enlarged cross-sectional view of area 4 of FIG. 3 according to one embodiment of the present disclosure. according to one embodiment of the present disclosure FIG. 5 is a cross-sectional view taken along line B-B′ of FIG. 2.

FIG. 6 is a cross-sectional view taken along line A-A′ of FIG. 2 according to one embodiment of the present disclosure.

FIG. 7 is a cross-sectional view taken along line A-A′ of FIG. 2 according to one embodiment of the present disclosure.

### DETAILED DESCRIPTION

Advantages and features of the present invention and methods of achieving them will become clear by referring to the embodiments described below in detail in conjunction with the accompanying drawings. However, the present invention is not limited to the embodiments disclosed below and can be implemented in various different forms, and these embodiments are merely provided to make the disclosure of the present invention complete and fully inform those skilled in the art to which the present invention pertains of the scope of the present invention, and the present invention is only defined by the scope of the appended claims.

Since shapes, sizes, ratios, angles, numbers, and the like disclosed in the drawings for describing the embodiments of the present invention are exemplary, the present invention is not limited to the shown items. The same reference numerals indicate the same components throughout the disclosure. In addition, in describing the present invention, when it is determined that the detailed description of a related known technology may unnecessarily obscure the gist of the present invention, the detailed description thereof will be omitted. When the terms “comprise,” “includes,” and “have” described in the present disclosure are used, other parts may be added unless “only” is used. When a component is expressed in the singular, it can be interpreted as a plurality of components unless specifically stated otherwise.

In interpreting a component, the component is interpreted as including the margin of error even when there is no separate explicit description.

In the case of describing a positional relationship, when the positional relationship between two parts such as “on,” “above,” “under,” “next to” is described, one or more other parts may be interposed between the two parts unless the term ‘immediately’ or ‘directly’ is used.

Although first, second, and the like are used to describe various components, these components are not limited by these terms. These terms are merely used to distinguish one component from another. Therefore, a first component described below may also be a second component within the technical spirit of the present invention.

The same reference numerals indicate the same components throughout the disclosure.

A size and thickness of each component shown in the drawings are shown for convenience of description, and the present invention is not necessarily limited to the size and thickness of the component shown.

Each feature of various embodiments of the present invention may be partially or fully coupled or combined with each other, and as those skilled in the art can fully understand, various technological interconnections and operations are possible, and each embodiment may be implemented independently of each other or implemented together in an associated relationship.

Hereinafter, display devices according to embodiments of the present disclosure will be described in detail with reference to the accompanying drawings.

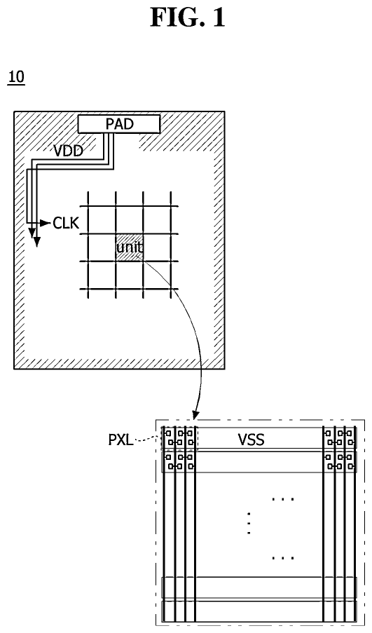

FIG. 1 is a plan view showing a display device 10 according to one embodiment of the present disclosure.

Referring to FIG. 1, the display device 10 may include a display area in which images are displayed and a non-display area in which the images are not displayed and driving circuits and wirings for transmitting signals to the display area are disposed.

In the non-display area, the driving circuits may be mounted and a pad portion PAD to which integrated circuits, printed circuits, etc. are connected may be disposed.

In the non-display area, a data driving circuit or a gate driving circuit may be disposed, and a controller for controlling a driving operation may be disposed.

The controller receives various timing signals including a clock signal CLK, an input data enable signal, and synchronization signals from the pad portion PAD.

The display device 10 may drive a light emitting element through a pixel driving transistor connected to a driving voltage VDD. The transistor includes a semiconductor element, source/drain electrodes, and a gate electrode, and the driving voltage VDD is applied to the light emitting element through a pixel electrode connected to the drain electrode. A high potential voltage EVDD wiring may be a pixel electrode or first electrode connected to the driving transistor of each pixel PXL, and a common voltage VSS wiring may be a cathode or second electrode connected to the light emitting element for a low potential voltage EVSS.

In addition, in the display device 10, a pixel driving circuit unit formed on a substrate may drive the pixel using a driving circuit chip. The pixel driving circuit unit may drive a plurality of pixels by transmitting signals output from the driving circuit chip, such as driving voltages, image signals (digital signals), and synchronization signals synchronized to the image signals and outputting the high potential voltage EVDD and the low potential voltage EVSS. The pixel driving circuit unit may receive the image signals and the synchronization signals from a host system. The host system may include a device such as a wearable system, a mobile system, a television (TV) system, a tablet computer, a notebook computer, a navigation system, or a personal computer (PC).

An electrode for the high potential voltage VDD or an electrode for the low potential voltage EVSS may be commonly formed on the entire surface of the display device.

The present disclosure describes an example in which the electrode for the low potential voltage EVSS is commonly formed, but is not limited thereto.

Referring to FIG. 1, the electrode for the low potential voltage VSS may be commonly disposed on the entire surface of the display device or commonly disposed for each pixel PXL row.

One pixel PXL may include one or more sub-pixels, such as red, green, and blue sub-pixels.

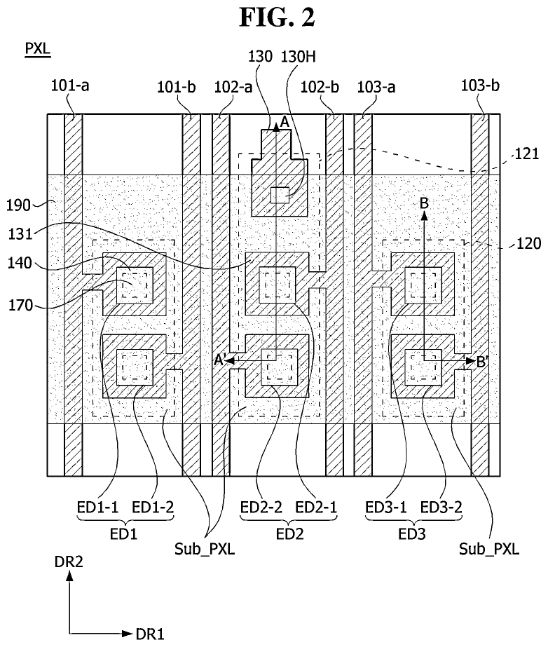

Referring to FIGS. 2 to 4, an enlarged plan view of a pixel PXL portion of FIG. 1 and a cross-sectional view of the pixel PXL portion are shown.

One sub-pixel (Sub PXL) may include at least one light emitting element, and when one light emitting element fails, the luminance of the sub-pixel Sub PXL may be adjusted by increasing the luminance of other light emitting elements in the sub-pixel Sub PXL.

The display device 10 may include a pixel driving circuit unit 200 disposed on a substrate 100, a buffer layer 110, planarization layers 111 and 112, and a plurality of wirings.

The substrate 100 may be formed of a flexible plastic. For example, the substrate 100 may be formed of a single layer or multiple layers made of materials such as polyimide, polyethylene terephthalate, polyethylene naphthalate, polycarbonate, polyethersulfone, polyarylate, polysulfone, a cyclic-olefin copolymer, etc., but is not limited thereto. The substrate 100 may also be formed of glass.

The pixel driving circuit unit 200 may be disposed on the substrate 100.

The pixel driving circuit unit 200 may include a plurality of thin film transistors using an amorphous silicon semiconductor, a polycrystalline silicon semiconductor, or an oxide semiconductor. The plurality of thin film transistors may include at least one driving thin film transistor, at least one switching thin film transistor, and at least one storage capacitor. When the pixel driving circuit unit 200 includes a plurality of thin film transistors, the pixel driving circuit unit 200 may be formed on the substrate 100 by TFT manufacturing processes.

In addition, the pixel driving circuit unit 200 may include a driving circuit chip.

The driving circuit chip may transmit a driving voltage for driving a light emitting element, an image signal (digital signal), a synchronization signal synchronized to the image signal, etc. to the light emitting element. When the pixel driving circuit unit 200 is a driving circuit chip, an adhesive layer may be further disposed between the substrate 100 and the pixel driving circuit unit 200.

The adhesive layer may be formed of acrylic resin, silicone resin, etc., but is not limited thereto.

The buffer layer 110 covering the pixel driving circuit unit 200 may be disposed on the substrate 100. The buffer layer 110 may be formed of an organic insulating material such as photosensitive photo acryl or photosensitive polyimide, but is not limited thereto.

In addition, the buffer layer 110 may be provided as multiple layers formed by stacking inorganic insulating materials, such as silicon nitride (SiNx) or silicon oxide (SiO2), or multiple layers formed by stacking an organic insulating material and an inorganic insulating material.

The buffer layer 110 may surround side surfaces of the pixel driving circuit unit 200 and cover a portion of an upper surface of the pixel driving circuit unit 200. An opening exposing a portion of the pixel driving circuit unit 200 may be disposed to expose a first contact electrode 210 and a second contact electrode 220 of the pixel driving circuit unit 200.

The plurality of planarization layers 111 and 112 may be disposed on the buffer layer 110. The plurality of planarization layers 111 and 112 may be formed of an organic insulating material such as a photosensitive photo acryl or photosensitive polyimide, but are not limited thereto.

A plurality of contact holes may be formed in the plurality of planarization layers 111 and 112 such that a first connecting wiring 230 and a third connecting wiring 250 that transmit signals of the first contact electrode 210 and a second connecting wiring 240 and a fourth connecting wiring 260 that transmit signals of the second contact electrode 220 of the pixel driving circuit unit 200 may be disposed on the first planarization layer 111 and the second planarization layer 112.

The first connecting wiring 230, the second connecting wiring 240, the third connecting wiring 250, and the fourth connecting wiring 260 may include at least one of titanium (Ti), molybdenum (Mo), aluminum (Al), indium tin oxide (ITO), and indium zinc oxide (IZO).

Protrusions 120 and 121 may be disposed on the third connecting wiring 250, the fourth connecting wiring 260, and a portion of the second planarization layer 112.

The protrusions 120 and 121 may be formed of an organic insulating material such as photosensitive photo acryl or photosensitive polyimide, but are not limited thereto.

A first connecting electrode 131 may be disposed on upper and side surfaces of the protrusions 120 and 121.

The first connecting electrode 131 may be formed by the same process as signal lines 101_a, 101_b, 102_a, 102_b, 103_a, and 103_b in FIG. 2 and may extend from the signal lines 101_a, 101_b, 102_a, 102_b, 103_a, and 103_b to be located on the upper and side surfaces of the protrusions 120 and 121.

The signal lines 101_a, 101_b, 102_a, 102_b, 103_a, and 103_b may extend in a second direction DR2 and may be disposed between the sub-pixels Sub PXL.

The first connecting electrode 131 may be disposed to extend from the signal lines 101_a, 101_b, 102_a, 102_b, 103_a, and 103_b in a first direction DR1 intersecting the second direction DR2. Since each sub-pixel Sub PXL includes two light emitting elements, when one light emitting element fails, it is possible to prevent a decrease in luminous efficiency by adjusting the luminance of the other light emitting element.

Referring to FIG. 2, each sub-pixel Sub PXL may have signal lines disposed at both sides thereof, and each sub-pixel Sub PXL may include a light emitting unit (not shown) including first light emitting elements ED1-1, ED2-1, and ED3-1 and second light emitting elements ED1-2, ED2-2, and ED3-2.

The first connecting electrode 131 and the signal lines 101_a, 101_b, 102_a, 102_b, 103_a, and 103_b may be the fourth connecting wiring 260 or may be separately formed and electrically connected to the fourth connecting wiring 260.

The protrusions 120 and 121 may include a first protrusion 120 and a second protrusion 121. The second protrusion 121 may be disposed to extend more than the first protrusion 120 in the second direction DR2.

The heights from an upper surface of the second planarization layer 112 to the upper surfaces of the protrusions 120 and 121 may be in the range of 1 to 5 μm.

In this case, the height from the substrate 110 to the upper surface of the second planarization layer 112 may be uniform.

A second connecting electrode 130 may be disposed on the upper and side surfaces of the second protrusions 121. The second connecting electrode 130 may be the third connecting wiring 250 or separately formed and electrically connected to the third connecting wiring 250.

The first connecting electrode 131 and the second connecting electrode 130 may be multiple layers including titanium (Ti), molybdenum (Mo), aluminum (Al), indium tin oxide (ITO), and indium zinc oxide (IZO).

The first connecting electrode 131 may be electrically connected to the second contact electrode 220 to transmit the high potential voltage EVDD from the pixel driving circuit unit 200 to the light emitting element, and the second connecting electrode 130 may be electrically connected to the first contact electrode 210 to transmit the low potential voltage EVSS from the pixel driving circuit unit 200 to the light emitting element.

Alternatively, the first connecting electrode 131 may be electrically connected to the second contact electrode 220 to transmit the low potential voltage EVSS from the pixel driving circuit unit 200 to the light emitting element, and the second connecting electrode 130 may be electrically connected to the first contact electrode 210 to transmit the high potential voltage EVDD from the pixel driving circuit unit 200 to the light emitting element, but the present disclosure is not limited thereto.

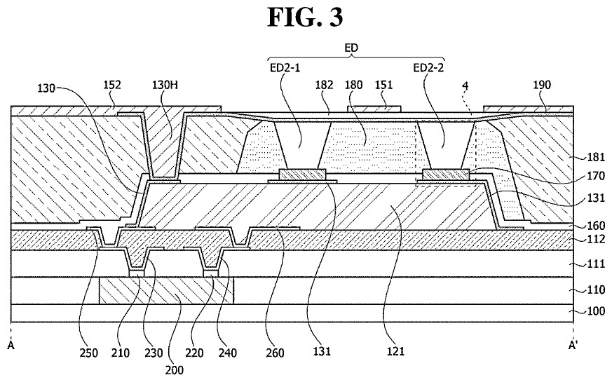

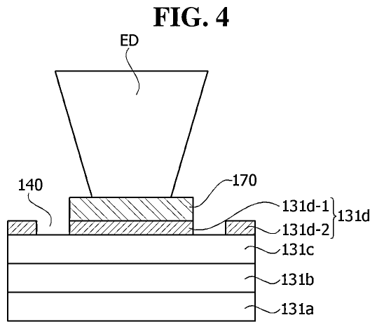

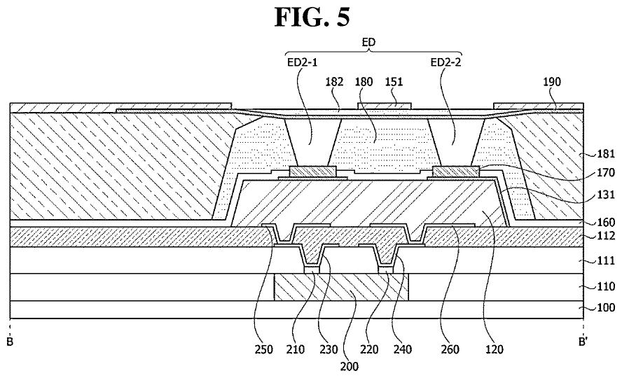

Referring to FIG. 4, FIG. 4 is an enlarged cross-sectional view of area 4 of FIG. 3 according to one embodiment of the present disclosure. The first connecting electrode 131 may be formed as a multilayered structure including a first layer 131a, a second layer 131b, a third layer 131c, and a fourth layer 131d.

The first layer 131a, the second layer 131b, the third layer 131c, and the fourth layer 131d may include titanium (Ti), molybdenum (Mo), or aluminum (Al).

The fourth layer 131d may include a transparent conductive oxide layer such as indium tin oxide (ITO) or indium zinc oxide (IZO) that has corrosion resistance and acid resistance.

By removing a portion of the fourth layer 131d in an area in which the light emitting element ED is not disposed, the fourth layer 131d may be divided into a 4-1 layer 131d-1 area in which the light emitting element ED is disposed and a 4-2 layer 131d-2 area disposed on an upper surface of the first layer 131a, the second layer 131b, and the third layer 131c.

The third layer 131c may be exposed in the area from which a portion of the fourth layer 131d is removed. The third layer 131c may be formed of a highly reflective metal material such as aluminum (Al) to increase luminous efficiency by reflecting the light from the top emission type light emitting element ED upward.

A protective layer 160 may be formed on the second planarization layer 112, the first connecting electrode 131, the second connecting electrode 130, and the second protrusion 121. The protective layer 160 may be provided as a multiple layer formed by stacking inorganic insulating materials such as silicon nitride (SiNx) or silicon oxide (SiO2).

The protective layer 160 on the 4-1 layer 131d-1 area in which the light emitting element ED is disposed may be removed by a process of removing a portion of the fourth layer 131d and dividing the fourth layer 131d into the 4-1 layer 131d-1 area in which the light emitting element ED is disposed and the 4-2 layer 131d-2 area,

An adhesive layer 170 may be disposed on the 4-1 layer 131d-1 area from which the protective layer 160 has been removed. The adhesive layer 170 may be formed of indium (In), tin (Sn), metal paste, or an alloy thereof, but is not limited thereto.

The light emitting elements ED1, ED2, and ED3 may be disposed on the adhesive layer 170. For example, one pixel PXL may include light emitting elements ED1, ED2, and ED3 having three colors. The first light emitting element ED1 may be a red light emitting element, the second light emitting element ED2 may be a green light emitting element, and the third light emitting element ED3 may be a blue light emitting element.

The light emitting elements ED1, ED2, and ED3 may have different shapes and sizes depending on the luminous efficiency of each sub-pixel Sub_PXL.

In addition, as shown, the light emitting elements ED1, ED2, and ED3 may have inverted tapered shapes to increase luminous efficiency in the case of a top emission type and have trapezoidal shapes or quadrangular shapes in the case of a bottom emission type.

The light emitting elements ED1, ED2, and ED3 may be inorganic light emitting diodes. The inorganic light emitting diodes may have a size of 1 μm to 50 μm or 1 μm to 20 μm in a horizontal direction (in an X-axis direction or a Y-axis direction). The inorganic light emitting diodes may be referred to as micro light emitting diodes. The inorganic light emitting diode may include a p-doped semiconductor layer, an active layer (e.g., including one or more quantum well layers), and an n-doped semiconductor layer. In addition, the inorganic light emitting diode may include a first pad electrode connected to the p-doped semiconductor layer and a second pad electrode connected to the n-doped semiconductor layer. The inorganic light emitting diodes may be manufactured using group II-VI or III-V compound semiconductors. The inorganic light emitting diodes may be manufactured by a separate manufacturing process and disposed on the adhesive layer 170 by a transfer process.

A metal layer for increasing a bonding strength with the adhesive layer 170 may be further disposed between the light emitting elements ED1, ED2, and ED3 and the adhesive layer 170. The metal layer may be an adhesive including gold (Au), metal paste, or a conductive material, but is not limited thereto.

A first insulating layer 180 may be disposed on an area in which the light emitting elements ED1, ED2, and ED3 are disposed and at least one side surface of each of the protrusions 120 and 121. The first insulating layer 180 may be formed of an organic insulating material and may further include scattering particles, such as titanium dioxide, to reflect or diffuse light as a material for increasing the light efficiency of the light emitting element ED. The first insulating layer 180 may be disposed to surround the peripheries of the light emitting elements ED1, ED2, and ED3, thereby improving the light emitting effect.

The first insulating layer 180 is disposed on the protrusions 120 and 121 on which the light emitting elements ED1, ED2, and ED3 are disposed to surround side and upper surface portions of the protrusions 120 and 121.

The first insulating layer 180 may be formed with a thick thickness of 1 to 60 μm, or 1 to 30 μm to surround the protrusions 120, 121 and the light emitting elements ED1, ED2, and ED3.

A second insulating layer 181 may be formed on the first insulating layer 180 and the entire surface of the substrate. The second insulating layer 181 may planarize the upper surface of the first insulating layer 180 and may be disposed to surround the side surfaces of the first insulating layer 180.

The second insulating layer 181 may be formed to be equal to or higher than the heights of the light emitting element ED and the protrusions 120 and 121.

The second insulating layer 181 may be formed of an organic insulating material such as siloxane, photosensitive photo acryl, or photosensitive polyimide, but is not limited thereto.

A contact hole 130H for exposing the second connecting electrode 130 may be formed in the second insulating layer 181. Since the contact hole 130H may expose the second connecting electrode 130 formed on the second protrusion 121 having a height of 1 μm to 5 μm, a depth of the contact hole 130H may be lower than the maximum height of the second insulating layer 181, which is 1 μm to 60 μm or 1 μm to 30 μm.

The first insulating layer 180 may have an opening formed to expose an upper portion of the light emitting element ED.

A second electrode 190 may be disposed on the upper portion of the light emitting element ED, the second insulating layer 181, and the contact hole 130H.

The second electrode 190 may be electrically connected to the second connecting electrode 130 to transmit the high potential voltage VDD or the low potential voltage VSS to the light emitting element ED.

On the second electrode 190, a third insulating layer 182 may be disposed in the opening area of the first insulating layer 180 formed on an upper portion of the light emitting element ED. The third insulating layer 182 may further include scattering particles, such as titanium dioxide, in an organic insulating film material. The third insulating layer 182 may be formed of the same material as the first insulating layer 180, may reflect or diffuse light as a material for increasing the light efficiency of the light emitting element ED and may planarize the upper surface.

A light blocking layer 151, 152 may be disposed on the second insulating layer 181, the second electrode 190, and the third insulating layer 182, where the light emitting element ED is not disposed.

The light blocking layer 151, 152 may be disposed on the entire surface of the substrate where the light emitting element ED is not disposed, and the light blocking layer 151, 152 may be formed by filling the contact hole 130H.

The light blocking layer 151, 152 may be formed of an organic material including a black material, but is not limited thereto.

FIG. 5 is a cross-sectional view taken along line B-B′ of FIG. 2 according to one embodiment. In describing the components of FIG. 5, description of components that are the same as or correspond to the components of FIGS. 2 to 4 will be omitted or simplified.

The second electrode 190 may be disposed to overlap the plurality of pixels PXL on an upper portion of the light emitting element ED. The second electrode 190 may be connected to the second connecting electrode 130 via the contact hole 130H for each pixel PXL or may be connected for the pixels PXL that are spaced a certain distance apart, but is not limited thereto.

In one pixel PXL, the second protrusion 121 for arrangement of the light emitting element ED and for connection of the second electrode 190 with the second connecting electrode 130 and the first protrusion 120 for arrangement of only the light emitting element ED may be disposed.

The first connecting electrode 131 may be disposed on the first protrusion 120, and the light emitting element ED may be disposed on the first connecting electrode 131.

The first insulating layer 180 surrounds at least two side surfaces of the first protrusion 120 and the side surfaces of the light emitting element ED.

The second electrode 190 and the third insulating layer 182 may be disposed on an upper portion of the light emitting element ED.

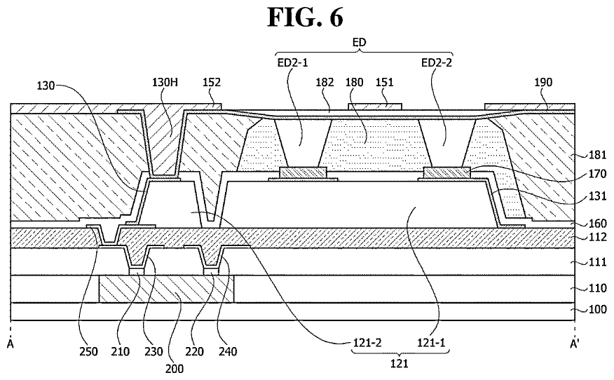

FIG. 6 is a cross-sectional view taken along line A-A′ of FIG. 2 according to one embodiment of the present disclosure. In describing the components of FIG. 6, description of components that are the same as or correspond to the components of FIGS. 2 to 4 will be omitted or simplified.

The second protrusion 121 may be disposed on the second planarization layer 112, the third connecting wiring 250, and the fourth connecting wiring 260.

The second protrusion 121 may include a 2-1 protrusion 121-1 and a 2-2 protrusion 121-2. The light emitting element ED may be disposed on the 2-1 protrusion 121-1, and the second connecting electrode 130 may be disposed on the 2-2 protrusion 121-2 and connected to the second electrode 190.

Since the 2-1 protrusion 121-1 and the 2-2 protrusion 121-2 are spaced apart from each other, it is possible to reduce the defects of the second connecting electrode 130 connected to the first connecting electrode 131 due to process errors when the second connecting electrode 130 is formed and clearly identify a location where the contact hole 130H of the second insulating layer 181 is formed.

The protective layer 160 may be formed in a separation portion between the 2-1 protrusion 121-1 and the 2-2 protrusion 121-2 and disposed to surround the 2-1 protrusion 121-1 and the 2-2 protrusion 121-2.

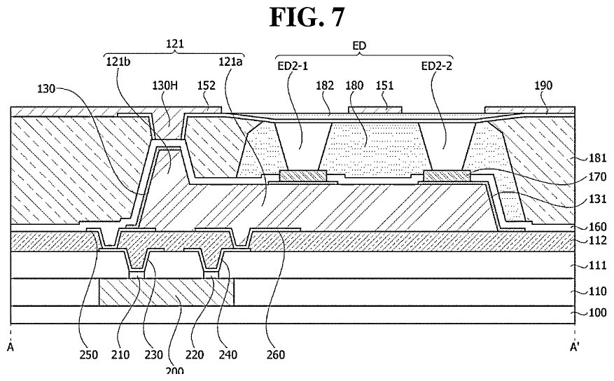

FIG. 7 is a cross-sectional view taken along line A-′A′ of FIG. 2 according to one embodiment of the present disclosure. In describing the components of FIG. 7, description of components that are the same as or correspond to the components of FIGS. 2 to 4 will be omitted or simplified.

The second protrusion 121 may be disposed on the second planarization layer 112, the third connecting wiring 250, and the fourth connecting wiring 260.

The second protrusion 121 may include a 2a protrusion 121a and a 2b protrusion 121b. The 2a protrusion 121a and the 2b protrusion 121b may be formed by the same process and may be integrally formed.

The light emitting element ED may be disposed in an area of the 2a protrusion 121a. A height from the upper surface of the second planarization layer 112 to an upper surface of the 2b protrusion 121b may be formed higher than a height from the upper surface of the second planarization layer 112 to an upper surface of the 2a protrusion 121a.

The second connecting electrode 130 may be disposed on the upper and side surfaces of the 2b protrusion 121b.

The protective layer 160, the light emitting element ED, the first insulating layer 180, and the second insulating layer 181 may be disposed on the second protrusion 121.

Since a height of the upper surface of the 2b protrusion 121b on which the second connecting electrode 130 is disposed may be formed higher than a height of the 2a protrusion 121a, a depth of the contact hole 130H of the second insulating layer 181 for exposing the second connecting electrode 130 may be formed lower than a height of the light emitting element ED.

The height from the upper surface of the second planarization layer 112 to the upper surface of the 2a protrusion 121a may be 1 μm to 5 μm, and the height from the upper surface of the second planarization layer 112 to the upper surface of the 2b protrusion 121b may be 1 μm to 50 μm or 1 μm to 20 μm.

In this case, a height from the substrate 110 to the upper surface of the second planarization layer 112 may be uniform.

Since the depth of the contact hole 130H is formed to be low, the second electrode 190 formed in the contact hole 130H may be prevented from being disconnected in the contact hole 130H, thereby stably implementing the connection with the second connecting electrode 130.

When a height of the 2b protrusion 121b is formed to be equal to or higher than that of the light emitting element ED, since the second connecting electrode 130 may be disconnected or not formed on the side surfaces of the 2b protrusion 121b, the height of the 2b protrusion 121b may be formed to be lower than that of the light emitting element ED.

A fourth insulating film and a protective film may be further disposed on the second electrode 190 and the light blocking layer 151, 152, and a touch part including a touch electrode for a touch operation may be disposed on the protective film.

In addition, if necessary, additional color filters may be further disposed in an area corresponding to the light emitting element, but are not limited thereto.

A display device according to embodiments of the present disclosure may be described as follows.

The display device according to the embodiments of the present disclosure may include a substrate including a display area and a non-display area, a plurality of pixels in the display area, wherein each pixel of the plurality of pixels may include a plurality of sub-pixels, at least one driving circuit unit for driving the plurality of pixels, a first protrusion and a second protrusion that are disposed on at least one pixel of the plurality of pixels, a first electrode formed on the first protrusion and the second protrusion, a light emitting unit disposed on the first electrode, and a second electrode disposed on the light emitting unit and connected to the light emitting unit, wherein the first protrusion and the second protrusion may have different widths in a second direction.

According to some embodiments of the present disclosure, the display device may further include a first insulating layer disposed on upper and side surfaces of the first protrusion and the second protrusion. According to some embodiments of the present disclosure, the display device may further include a second insulating layer disposed on a side surface of the first insulating layer and the substrate, and the first insulating layer may include light scattering particles.

According to some embodiments of the present disclosure, the second insulating layer may be in contact with at least one side surface of the second protrusion.

According to some embodiments of the present disclosure, the second protrusion may have a width greater than that of the first protrusion in the second direction.

According to some embodiments of the present disclosure, the display device may further include a connecting electrode disposed on the second protrusion, and the connecting electrode may be connected to the second electrode.

According to some embodiments of the present disclosure, the second protrusion may include a first area in which a light emitting unit is disposed and a second area in which the connecting electrode is disposed.

According to some embodiments of the present disclosure, the first area and the second area may be disposed to be spaced apart from each other.

According to some embodiments of the present disclosure, the heights of the upper surfaces of the first area and the second area from the substrate may be different.

According to some embodiments of the present disclosure, a height from the substrate to the upper surface of the second area may be higher than a height from the substrate to the upper surface of the first area, and the connecting electrode may be disposed on the upper surface of the second area.

According to some embodiments of the present disclosure, the display device further comprises a contact hole above the second area and the second electrode is connected with the connecting electrode via the contact hole.

According to some embodiments of the present disclosure, wherein the contact hole has a depth lower than a height of the light emitting unit.

A display device according to embodiments of the present disclosure may include a substrate including a display area and a non-display area disposed on at least one side of the display area, a driving circuit unit disposed in the display area, and a plurality of pixels electrically connected to the driving circuit unit, in which each of the plurality of pixels may include a plurality of sub-pixels, at least two light emitting elements may be disposed in each of the plurality of sub-pixels, the light emitting elements may be electrically connected to the driving circuit unit via a first connecting electrode and a second connecting electrode, and the first connecting electrode may be formed on first and second protrusions and the second connecting electrode may be formed on the second protrusion.

According to some embodiments of the present disclosure, the first connecting electrode may be connected to the light emitting element on the first and second protrusions, and the second connecting electrode may be connected to the light emitting element via a second electrode on the second protrusion.

According to some embodiments of the present disclosure, the first protrusion and the second protrusion may have different widths in a second direction.

According to some embodiments of the present disclosure, the second protrusion may have a width greater than that of the first protrusion in the second direction.

According to some embodiments of the present disclosure, the second protrusion may include a first area in which the light emitting element is disposed and a second area in which the second connecting electrode is disposed.

According to some embodiments of the present disclosure, the first area and the second area may be disposed to be spaced apart from each other.

According to some embodiments of the present disclosure, the heights of the upper surfaces of the first area and the second area from the substrate may be different.

According to some embodiments of the present disclosure, the display device may further include a first insulating layer disposed on the upper and side surfaces of the first protrusion and the second protrusion.

According to some embodiments of the present disclosure, the display device may further include a second electrode and a third insulating layer, in which the first insulating layer may have an opening exposing the upper surface of the light emitting element, the second electrode may be disposed in the opening, and the third insulating layer may be disposed on the second electrode.

According to some embodiments of the present disclosure, the first insulating layer and the third insulating layer may be formed of the same material and may include light scattering particles.

According to some embodiments of the present disclosure, a height from the substrate to the upper surface of the second area is higher than a height from the substrate to the upper surface of the first area, and the second connecting electrode is disposed on the upper surface of the second area.

According to some embodiments of the present disclosure, the display device further comprises a contact hole above the second area and the second electrode is connected with the connecting electrode via the contact hole.

According to some embodiments of the present disclosure, wherein the contact hole has a depth lower than a height of the light emitting unit.

According to embodiments of the present disclosure, it is possible to stably

implement the connection with a second electrode by arranging a connecting electrode on a protrusion on which a light emitting element is disposed on a substrate.

According to embodiments of the present disclosure, by forming a contact hole in an insulating film disposed on the protrusion, a depth of the contact hole can be easily adjusted to reduce poor contact with a second electrode, thereby improving the reliability of the display device.

Effects of the present disclosure are not limited to those mentioned above, and other effects not mentioned will be clearly understood by those skilled in the art from the above description.

Although embodiments of the present disclosure have been described in detail with reference to the accompanying drawings, the present disclosure is not necessarily limited to these embodiments and may be modified in various ways without departing from the technical spirit of the present disclosure. Therefore, the embodiments disclosed in the present disclosure are not intended to limit the technical spirit of the present disclosure, but are for illustrative purposes, and the scope of the technical spirit of the present disclosure is not limited by these embodiments. The scope of the present disclosure should be interpreted in accordance with the appended claims, and all technical ideas within the equivalent scope therewith should be interpreted as being included in the scope of the present disclosure.

What is claimed is:

1. A display device comprising:
a substrate including a display area and a non-display area;
a plurality of pixels in the display area, wherein each pixel of the plurality of pixels includes a plurality of sub-pixels;
at least one driving circuit configured to drive the plurality of pixels;
a first protrusion and a second protrusion that are on at least one pixel of the plurality of pixels;
a first electrode on the first protrusion and the second protrusion;
a light emitting element on the first electrode; and
a second electrode on the light emitting element, the second electrode connected to the light emitting element,
wherein the first protrusion and the second protrusion have different widths in a second direction.

2. The display device of claim 1, further comprising:
a first insulating layer on an upper surface and a side surface of the first protrusion and the second protrusion.

3. The display device of claim 2, further comprising:
a second insulating layer on a side surface of the first insulating layer and the substrate,
wherein the first insulating layer includes light scattering particles.

4. The display device of claim 3, wherein the second insulating layer is in contact with at least one side surface of the second protrusion.

5. The display device of claim 1, wherein the second protrusion has a width greater than a width of the first protrusion in the second direction.

6. The display device of claim 5, further comprising:
a connecting electrode on the second protrusion, the connecting electrode connected to the second electrode.

7. The display device of claim 6, wherein the second protrusion includes a first area in which the light emitting element is disposed and a second area in which the connecting electrode is disposed.

8. The display device of claim 7, wherein the first area and the second area are spaced apart from each other.

9. The display device of claim 7, wherein heights of an upper surface of the first area and an upper surface of the second area from the substrate are different.

10. The display device of claim 9, wherein a height from the substrate to the upper surface of the second area is higher than a height from the substrate to the upper surface of the first area, and the connecting electrode is on the upper surface of the second area.

11. The display device of claim 10, further comprises:
a contact hole above the second area and the second electrode is connected with the connecting electrode via the contact hole.

12. The display device of claim 11, wherein the contact hole has a depth that is lower than a height of the light emitting element.

13. A display device comprising:
a substrate including a display area and a non-display area on at least one side of the display area;
a driving circuit in the display area; and
a plurality of pixels electrically connected to the driving circuit, each of the plurality of pixels including a plurality of sub-pixels,
at least two light emitting elements are in each of the plurality of sub-pixels,
wherein the at least two light emitting elements are electrically connected to the driving circuit via a first connecting electrode and a second connecting electrode, and the first connecting electrode is on a first protrusion and a second protrusion and the second connecting electrode is on the second protrusion.

14. The display device of claim 13, wherein the first connecting electrode is connected to a light emitting element from the at least two light emitting elements on the first protrusion and the second protrusion, and the second connecting electrode is connected to the light emitting element via a second electrode on the second protrusion.

15. The display device of claim 13, wherein the first protrusion and the second protrusion have different widths in a second direction.

16. The display device of claim 15, wherein the second protrusion has a width that is greater than a width of the first protrusion in the second direction.

17. The display device of claim 16, wherein the second protrusion includes a first area in which a light emitting element from the at least two light emitting elements is disposed and a second area in which the second connecting electrode is disposed.

18. The display device of claim 17, wherein the first area and the second area are spaced apart from each other.

19. The display device of claim 17, wherein heights of upper surfaces of the first area and the second area from the substrate are different.

20. The display device of claim 13, further comprising:
a first insulating layer on an upper surface and a side surface of the first protrusion and the second protrusion.

21. The display device of claim 20, further comprising:
a second electrode and a third insulating layer,
wherein the first insulating layer has an opening exposing an upper surface of a light emitting element from the at least two light emitting elements, the second electrode is in the opening, and the third insulating layer is on the second electrode.

22. The display device of claim 21, wherein the first insulating layer and the third insulating layer include a same material and include light scattering particles.

23. The display device of claim 19, wherein a height from the substrate to an upper surface of the second area is higher than a height from the substrate to an upper surface of the first area, and the second connecting electrode is on the upper surface of the second area.

24. The display device of claim 23, further comprises:
a contact hole above the second area and a second electrode is connected with the second connecting electrode via the contact hole.

25. The display device of claim 24, wherein the contact hole has a depth that is lower than a height of a light emitting element from the at least two light emitting elements.
